(19) United States
(12) Patent Application Publication
(10) Pub. No.: US 2014/0069323 A1
(43) Pub. Date: Mar. 13, 2014

(54) Method for Forming a Metal Chalcogenide

(71) Applicants: Yen-Chau WANG, Taichung (TW); Hsiao-Chun CHU, Taichung (TW); Wang-Lin LIU, Taichung (TW)

(72) Inventors: Yen-Chau WANG, Taichung (TW); Hsiao-Chun CHU, Taichung (TW); Wang-Lin LIU, Taichung (TW)

(73) Assignee: Precision Machinery Research & Development Center, Taichung (TW)

(21) Appl. No.: 13/611,485

(22) Filed: Sep. 12, 2012

(51) Int. Cl. C30B 1/02

(52) U.S. Cl. 117/8

(57) ABSTRACT

A method for forming a metal chalcogenide includes: (a) providing a preliminary precursor solution including a first precursor for an elemental metal of Ag, Au, Al, In, Ga, or Tl, a second precursor for a chalcogen element of Se, S, or Te, and a liquid solvent; (b) heating the preliminary precursor solution under an inert ambient, such that the first precursor reacts with the second precursor to obtain a metal chalcogenide precursor that is in an amorphous phase; (c) removing the liquid solvent from the metal chalcogenide precursor; and (d) heating the metal chalcogenide precursor under a hydrogen-containing gas pressure so as to convert the metal chalcogenide precursor into a single crystal phase metal chalcogenide.

### BACKGROUND OF THE INVENTION

1. Field of the Invention

This invention relates to a method for forming a metal chalcogenide, more particularly to a method for forming a binary metal chalcogenide.

2. Description of the Related Art

Copper indium diselenide (CuInSe₂, CIS) and copper indium gallium diselendie (CuInGaSe₂, CIGS) have been studied to serve as light absorbing materials of solar cells since they are highly efficient in converting solar energy into electrical energy, and since the materials for forming CIS and CIGS are relatively inexpensive.

Generally, a film of light absorbing material is formed by simultaneously depositing elements of Cu, In, Ga, Se and so on, on a substrate at a substrate temperature ranging from 500° C. to 600° C. using vacuum co-evaporation. However, the production cost involved is relatively high.

The light adsorbing material may also be made by vapor depositing or sputtering a film of metallic or binary precursor on a substrate, followed by selenization or sulfation of the film. However, the selenization of the film is performed using highly toxic gases (such as hydrogen selenide).

Besides, a film of CIS or CIGS may be formed using binary or multinary metal chalcogenides, such as CuSe, CuS, In₂Se₃, etc. U.S. Pat. No. 7,829,059 discloses that metal chalcogenide nanoparticles can be synthesized by reacting metal components (CuCl, InCl₃) with a chalcogen precursor (Se powder) in the presence of a solvent having at least one boiling point equal to 220° C. or above and a chain length of about 12 carbon atoms or above (such as oleylamine).

In U.S. 2012/0094431, it is disclosed that elemental selenium can be first subjected to a reduction reaction by a nitrogen-containing agent (hydrazine), and then mixed with a metal salt (indium chloride) to obtain a metal chalcogen (indium selenide precursor).

### SUMMARY OF THE INVENTION

An object of the present invention is to provide a method for forming a metal chalcogenide that is in a single crystal phase, and that has a relatively high purity.

Accordingly, a method for forming a metal chalcogenide includes: (a) providing a preliminary precursor solution including a first precursor for an elemental metal selected from the group consisting of Ag, Au, Al, In, Ga, Tl and combinations thereof, a second precursor for a chalcogen element selected from the group consisting of Se, S, and Te, and a liquid solvent; (b) subjecting the preliminary precursor solution to a first heating treatment under an inert ambient, such that the first precursor reacts with the second precursor to obtain a metal chalcogenide precursor that is in an amorphous phase; (c) removing the liquid solvent from the metal chalcogenide precursor; and (d) subjecting the metal chalcogenide precursor to a second heating treatment under a hydrogen-containing gas pressure so as to convert the metal chalcogenide precursor into a single crystal phase metal chalcogenide.

Preferably, the hydrogen-containing gas pressure has a partial pressure of hydrogen gas ranging from 1 to 100 percent of the hydrogen-containing gas pressure, and the balance is attributed to an inert gas.

The inventor of this application first found that when the second heating treatment is implemented in the presence of hydrogen gas, the single crystal phase metal chalcogenide thus formed has a very high purity and is very useful for forming films of CIS or CIGS of a relatively high quality.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 shows an X-ray diffraction pattern of indium selenium produced in Example 1 of this invention;

FIG. 2 shows a scanning electron microscope image of indium selenium produced in Example 1 of this invention;

FIG. 3 shows an X-ray diffraction pattern of indium selenium produced in Example 2 of this invention; and

FIG. 4 shows an X-ray diffraction pattern of indium selenium produced in Comparative Example.

### DETAILED DESCRIPTION OF THE PREFERRED EMBODIMENTS

A preferred embodiment of a method for forming a metal chalcogenide according to this invention includes steps (a) to (d).

In step (a), a preliminary precursor solution is provided. The preliminary precursor solution includes a first precursor for an elemental metal selected from Ag, Au, Al, In, Ga, Tl and combinations thereof, a second precursor for a chalcogen element of Se, S, or Te, and a liquid solvent.

In step (b), the preliminary precursor solution is subjected to a first heating treatment under an inert ambient, such that the first precursor reacts with the second precursor to obtain a metal chalcogenide precursor that is in an amorphous phase.

In step (c), the liquid solvent is removed from the metal chalcogenide precursor.

In step (d), the metal chalcogenide precursor is subjected to a second heating treatment under a hydrogen-containing gas pressure so as to convert the metal chalcogenide precursor into a single crystal phase metal chalcogenide. The hydrogen-containing gas pressure has a partial pressure of hydrogen gas ranging from 1 to 100 percent of the hydrogen-containing gas pressure, and the balance is attributed to an inert gas. The inert gas may be nitrogen gas or argon gas.

Preferably, the partial pressure of the hydrogen gas ranges from 20 to 50 percent of the hydrogen-containing gas pressure.

The metal chalcogenide precursor is unstable, can be preserved under an inert ambient for several days, and discolors when exposed to air. The metal chalcogenide precursor can be found to be in the amorphous phase when being analyzed by X-ray diffraction.

The single crystal phase metal chalcogenide obtained in step (d) may be a binary or multinary metal chalcogenide. Preferably, the single crystal phase metal chalcogenide is a binary metal chalcogenide. It is found that if the hydrogen gas is not introduced in step (d), the metal chalcogenide precursor will not be converted to have a single crystal phase, may have impurities (for example, a residual of first and second precursors), and thus, the yield of the metal chalcogenide is relatively low.

Preferably, step (c) is implemented by cleaning the metal chalcogenide precursor using ultrapure water, followed by drying.

Preferably, the elemental metal is In, and the chalcogen element is Se. The synthesis of indium selenide, especially the single crystal phase In₂Se₃, is costly in the past. With the method of this invention, the single crystal phase In₂Se₃ can be easily synthesized in a more simplified/efficient manner, and thus, mass production of the single crystal phase In₂Se₃ is facilitated.

Preferably, the first heating treatment is implemented at a temperature ranging from 120° C. to 250° C.

Preferably, the first heating treatment is implemented for a time period ranging from 10 hours to 25 hours.

The second heating treatment is implemented at a temperature ranging preferably from 400° C. to 700° C., and more preferable from 450° C. to 650° C.

The hydrogen-containing gas pressure ranges preferably from 7.36×10⁻² torr, and more preferably from 7.36×10⁻¹ torr to 7.36×10¹ torr. The second heating treatment is implemented for a time period ranging preferably from 15 minutes to 3 hours, and more preferably from 30 minutes to 1 hour.

Preferably, the liquid solvent includes a metal chelating agent selected from ethylene diamine, triethylene tetramine, divinylamine, and oleylamine. Ethylene diamine is more preferable.

The present invention is explained in more detail below by way of the following examples and comparative example. It should be noted that the examples are provided herein for exemplification purposes only and are not intended to limit the scope of this invention.

### EXAMPLE 1

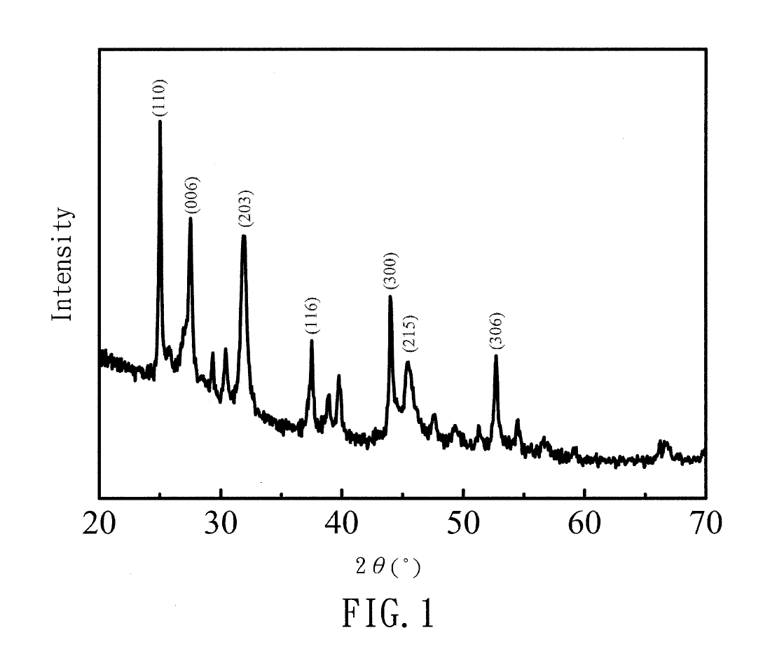

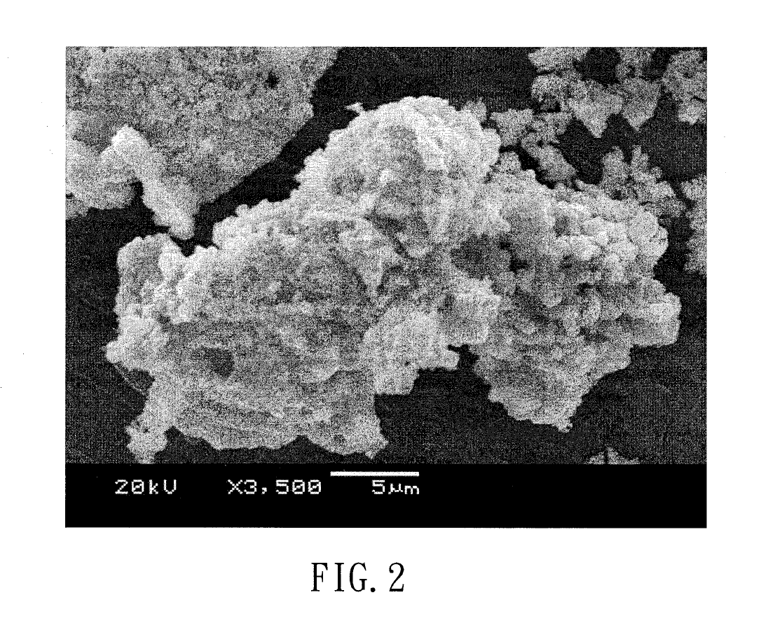

A preliminary precursor solution was prepared by adding 0.28 g of InCl₃ (ACROS, reagent grade) and 0.20 g of Se powder (ACROS, reagent grade) into 40 ml of ethylene diamine, followed by stirring to disperse the InCl₃ and the Se powder in the ethylene diamine. Then, the preliminary precursor solution was poured into a sealed reactor, and was subjected to the first heating treatment at 200° C. for 15 hours under an inert ambient. Thereafter, an indium selenide precursor in an amorphous phase was obtained. The indium selenide precursor was removed from the sealed reactor and cleaned using ultrapure water, followed by drying at 60° C. for 6 hours. The cleaned indium selenide precursor was then placed in a tubular furnace, and hydrogen gas was introduced into the tubular furnace such that only the hydrogen gas is present in the gaseous atmosphere within the tubular furnace. The indium selenide precursor was subjected to the second heating treatment in the tubular furnace at 550° C. for 1 hour. Finally, a product powder was obtained and analyzed using an X-ray diffraction system (Philips X′pert Pro MPD). The result, i.e., the X-ray diffraction pattern of Example 1, is shown in FIG. 1. By comparing the X-ray diffraction pattern of Example 1 with Joint Committee on Powder Diffraction Standards # 40-1407, it is found that the X-ray diffraction pattern has major diffraction peaks which can be indexed to (110), (006), (116), (300), and (306) planes of a single crystal phase In₂Se₃. In other words, the product powder is a single crystal phase In₂Se₃ without impurity. The product powder was observed using a scanning electron microscope (HITACHI, S3000H), and was found to have irregular structures (see FIG. 2).

### EXAMPLE 2

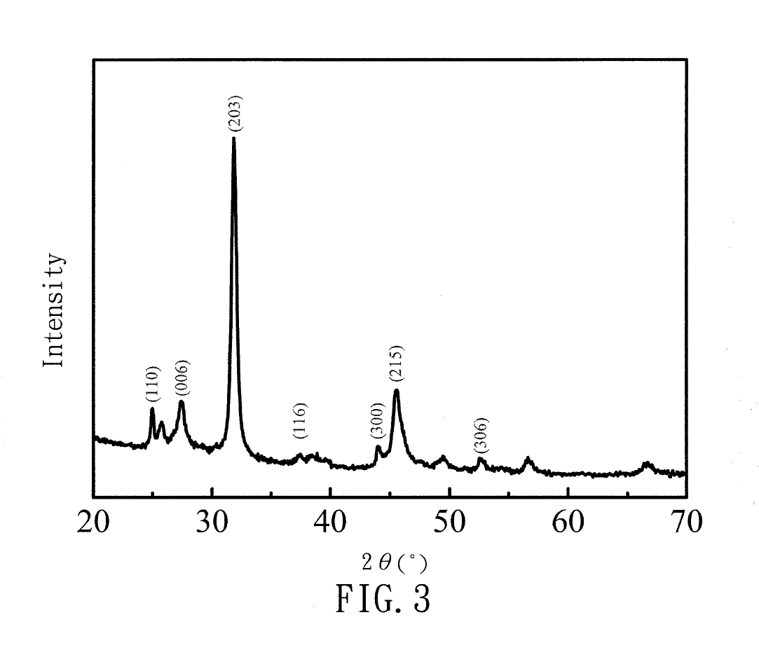

A preliminary precursor solution was prepared by adding 0.28 g of InCl₃ (ACROS, reagent grade) and 0.20 g of Se powder (ACROS, reagent grade) into 40 ml of ethylene diamine, followed by stirring to disperse the InCl₃ and the Se powder in the ethylene diamine. Then, the preliminary precursor solution was poured into a sealed reactor, and was subjected to the first heating treatment at 200° C. for 15 hours under an inert ambient. Thereafter, an indium selenide precursor in an amorphous phase was obtained. The indium selenide precursor was removed from the sealed reactor and cleaned using ultrapure water, followed by drying at 60° C. for 6 hours. The cleaned indium selenide precursor was then placed in a tubular furnace, and hydrogen gas and nitrogen gas were introduced into the tubular furnace such that a partial pressure attributed to the hydrogen gas was equal to 93% of the total pressure inside the tubular furnace, the balance being attributed to the nitrogen gas. The indium selenide precursor was then subjected to the second heating treatment in the tubular furnace at 550° C. for 1 hour. Finally, a product powder was obtained and analyzed using an X-ray diffraction system (Philips X′pert Pro MPD). The result, i.e., the X-ray diffraction pattern of Example 2, is shown in FIG. 3. By comparing the X-ray diffraction pattern of Example 2 with Joint Committee on Powder Diffraction Standards #40-1407, it is found that the X-ray diffraction pattern has major diffraction peaks which can be indexed to (110), (006), (116), (300), and (306) planes of a single crystal phase In₂Se₃. In other words, the product powder is a single crystal phase In₂Se₃ without impurity. The product powder was observed using a scanning electron microscope (HITACHI, 53000H), and was found to have irregular structures.

COMPARATIVE EXAMPLE

The product powder of Comparative Example was prepared following the procedure employed in Example 1 except that only nitrogen was introduced into the tubular furnace such that only the nitrogen gas is present in the gaseous atmosphere within the tubular furnace. Thus, in the Comparative Example, the indium selenide precursor was heated in the absence of the hydrogen gas.

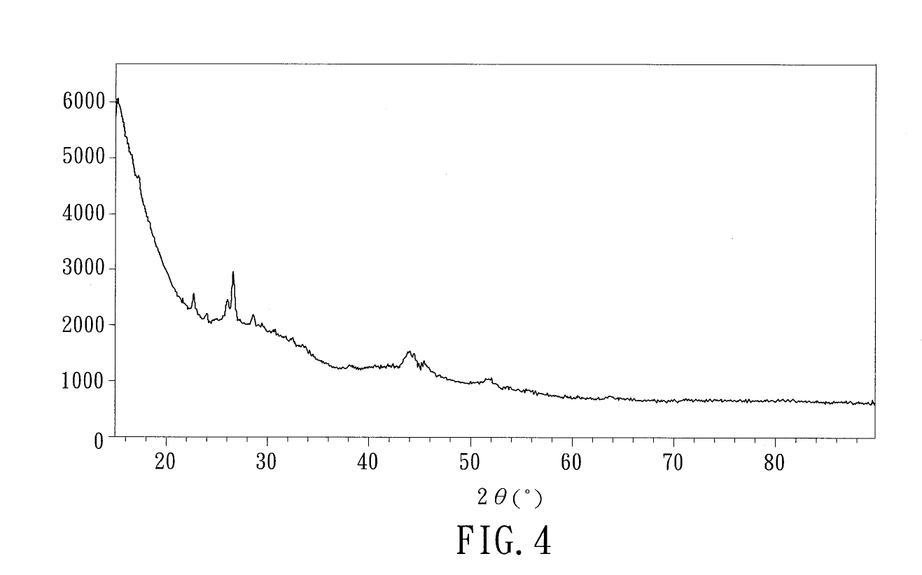

FIG. 4 shows an X-ray diffraction pattern of the Comparative Example. It is found that the X-ray diffraction pattern of the Comparative Example mismatches Joint Committee on Powder Diffraction Standards # 40-1407.

From the results of Examples 1 and 2, it can be seen that the indium selenide precursor subjected to the heating treatment in the presence of hydrogen gas can be converted into a single crystal phase In₂Se₃. In the Comparative Example, the indium selenide precursor subjected to the heating treatment in the absence of the hydrogen gas could not be converted to have a single crystal phase. Thus, it can be concluded that only heated the indium selenide precursor under the influence of the hydrogen gas pressure can be converted into a single crystal phase In₂Se₃.

In sum, with the method of this invention, a single crystal metal chalcogenide of very high purity can be formed without using a vacuum system or a selenization process.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A method for forming a metal chalcogenide comprising:
(a) providing a preliminary precursor solution including a first precursor for an elemental metal selected from the group consisting of Ag, Au, Al, In, Ga, Tl and combinations thereof, a second precursor for a chalcogen element selected from the group consisting of Se, S, and Te, and a liquid solvent;
(b) subjecting the preliminary precursor solution to a first heating treatment under an inert ambient, such that the first precursor reacts with the second precursor to obtain a metal chalcogenide precursor that is in an amorphous phase;
(c) removing the liquid solvent from the metal chalcogenide precursor; and
(d) subjecting the metal chalcogenide precursor to a second heating treatment under a hydrogen-containing gas pressure so as to convert the metal chalcogenide precursor into a single crystal phase metal chalcogenide.

2. The method of claim 1, wherein the elemental metal is In, and the chalcogen element is Se.

3. The method of claim 1, wherein the hydrogen-containing gas pressure has a partial pressure of hydrogen gas ranging from 1 to 100 percent of the hydrogen-containing gas pressure, the balance being attributed to an inert gas.

4. The method of claim 3, wherein the partial pressure of the hydrogen gas ranges from 20 to 50 percent of the hydrogen-containing gas pressure.

5. The method of claim 1, wherein the first heating treatment is implemented at a temperature ranging from 120° C. to 250° C.

6. The method of claim 1, wherein the first heating treatment is implemented for a time period ranging from 10 hours to 25 hours.

7. The method of claim 1, wherein the second heating treatment is implemented at a temperature ranging from 400° C. to 700° C.

8. The method of claim 1, wherein the second heating treatment is implemented for a time period ranging from 15 minutes to 25 hours.

9. The method of claim 1, wherein the liquid solvent includes a metal chelating agent.

10. The method of claim 9, wherein the metal chelating agent is selected from the group consisting of ethylene diamine, triethylene tetramine, divinylamine, and oleylamine.

11. The method of claim 1, wherein step (c) is implemented by drying.
